(19) United States
(12) Patent Application Publication
(10) Pub. No.: US 2022/0344355 A1
(43) Pub. Date: Oct. 27, 2022

(54) MULTI-GATE DEVICE GATE STRUCTURE AND METHODS THEREOF

(71) Applicant: Taiwan Semiconductor Manufacturing Company, Ltd., Hsinchu (TW)

(72) Inventors: Shih-Hao LIN, Hsinchu (TW); Chih-Wei LEE, New Taipei City (TW); Shang-Rong LI, Hsinchu City (TW); Chih-Chuan YANG, Hsinchu (TW); Chia-Hao PAO, Kaohsiung City (TW); Chien-Chih LIN, Taichung City (TW)

(21) Appl. No.: 17/465,314

(22) Filed: Sep. 2, 2021

Related U.S. Application Data
(60) Provisional application No. 63/178,765, filed on Apr. 23, 2021.

(51) Int. Cl. H01L 27/11; H01L 29/423; H01L 29/786; H01L 29/66; H01L 21/02

(52) U.S. Cl. CPC H01L 27/1108; H01L 29/42392; H01L 29/78696; H01L 29/66742; H01L 21/02315; H01L 21/0234

(57) ABSTRACT

A method and structure for modulating a threshold voltage of a device. In various embodiments, a fin extending from a substrate is provided. In some embodiments, the fin includes a plurality of semiconductor channel layers defining a channel region for a P-type transistor. In some examples, a gate dielectric is formed wrapping around each of the plurality of semiconductor channel layers of the P-type transistor. In some cases, a P-type work function (PWF) metal gate cap is formed wrapping around the gate dielectric. In various embodiments, the PWF metal gate cap merges between adjacent semiconductor channel layers of the plurality of channel layers. Additionally, in some examples, the PWF metal gate cap includes a plurality of nitrogen-containing layers.

### CROSS-REFERENCE TO RELATED APPLICATION

This application claims the benefit of U.S. Provisional Application No. 63/178,765, filed Apr. 23, 2021, the entirety of which is incorporated by reference herein.

### BACKGROUND

The electronics industry has experienced an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). Thus far these goals have been achieved in large part by scaling down semiconductor IC dimensions (e.g., minimum feature size) and thereby improving production efficiency and lowering associated costs. However, such scaling has also introduced increased complexity to the semiconductor manufacturing process. Thus, the realization of continued advances in semiconductor ICs and devices calls for similar advances in semiconductor manufacturing processes and technology.

Recently, multi-gate devices have been introduced in an effort to improve gate control by increasing gate-channel coupling, reduce OFF-state current, and reduce short-channel effects (SCEs). One such multi-gate device that has been introduced is the gate-all-around (GAA) transistor. GAA transistors get their name from the gate structure which extends completely around the channel, providing excellent electrostatic control of the channel. GAA transistors also provide high drive currents and are compatible with conventional complementary metal-oxide-semiconductor (CMOS) processes. Further, their three-dimensional structure allows them to be aggressively scaled while maintaining gate control and mitigating SCEs.

However, despite having many desirable features, GAA transistor fabrication has continued to face challenges as a result of the ongoing scaling down of semiconductor IC dimensions. Thus, existing techniques have not proved entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 provides a simplified top-down layout view of a multi-gate device, in accordance with some embodiments;

FIG. 2 is a flow chart of a method of fabrication of a multi-gate device, in accordance with some embodiments;

FIGS. 3, 4, 5, and 6 provide cross-sectional views of an embodiment of a semiconductor device along a plane substantially parallel to a plane defined by section AA′ of FIG. 1, at different stages of processing according to the method of FIG. 2, in accordance with some embodiments;

FIG. 7A illustrates an enlarged view of a gate stack for a device fabricated to include a work function metal gate cap, in accordance with some embodiments;

FIG. 7B illustrates an enlarged view of a gate stack for a device fabricated using a combination of both the work function metal gate cap and a plasma treatment process, in accordance with some embodiments;

FIG. 7C illustrates an example of forming a P-dipole for a P-type transistor and FIG. 7D illustrates an example of forming N-dipole for an N-type transistor, in accordance with some embodiments;

FIG. 8 provides a plot showing an atomic percent of oxygen as a function of depth for a baseline device, a device fabricated to include the work function metal gate cap, and a device fabricated using a combination of both the work function metal gate cap and a plasma treatment process, in accordance with some embodiments;

FIG. 9 provides a plot showing X-ray photoelectron spectroscopy (XPS) data for an oxygen (1s) signal as a function of binding energy for a baseline device, a device fabricated to include the work function metal gate cap, and a device fabricated using a combination of both the work function metal gate cap and a plasma treatment process, in accordance with some embodiments;

FIG. 10 illustrates a more detailed flow chart of a portion of the method of FIG. 2, including formation of the work function metal gate cap and performing of the plasma treatment process, in accordance with various embodiments; and

FIG. 11 provides a graph comparing the flatband voltage shift of a device with the work function metal gate cap, but without plasma treatment, and the flatband voltage shift of a device with the work function metal gate cap and plasma treatment, to a baseline device, according to some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Additionally, in the discussion that follows, dimensions (e.g., such as thickness, width, length, etc.) for a given layer or other feature may at times be described using terms such as “substantially equal”, “equal”, or “about”, where such terms are understood to mean within +/−10% of the recited value or between compared values. For instance, if dimension A is described as being “substantially equal” to dimension B, it will be understood that dimension A is within +/−10% of dimension B. As another example, if a layer is described as having a thickness of about 100 nm, it will be understood that the thickness of the layer may in a range between 90-110 nm.

It is also noted that the present disclosure presents embodiments in the form of multi-gate transistors, including methods of gate stack formation such transistors. Multi-gate transistors include those transistors whose gate structures are formed on at least two-sides of a channel region. These multi-gate devices may include a P-type metal-oxide-semiconductor device or an N-type metal-oxide-semiconductor multi-gate device. Specific examples may be presented and referred to herein as FinFETs, on account of their fin-like structure. Also presented herein are embodiments of a type of multi-gate transistor referred to as a gate-all-around (GAA) transistor. A GAA transistor includes any device that has its gate structure, or portion thereof, formed on 4-sides of a channel region (e.g., surrounding a portion of a channel region). Devices presented herein also include embodiments that have channel regions disposed in semiconductor channel layers. In various embodiments, the semiconductor channel layers may include nanosheet channel(s), nanowire channel(s), bar-shaped channel(s), and/or other suitable channel configurations. Presented herein are embodiments of devices that may have one or more channel regions (e.g., semiconductor channel layers) associated with a single, contiguous gate structure. However, one of ordinary skill would recognize that the teaching can apply to a single channel (e.g., single semiconductor channel layer) or any number of channels. One of ordinary skill may recognize other examples of semiconductor devices that may benefit from aspects of the present disclosure.

Static random-access memory (SRAM) devices are a key element for logic circuitry, the operation of which is defined by their static noise margin (SNM), read margin, and write margin, which are related to the threshold voltages of the N-type and P-type transistors used to implement the SRAM device. For advanced, highly-scaled SRAM devices implemented using GAA transistors, there are a variety of existing challenges. As one example, SRAM read margin and pull-up (PU) threshold voltage (Vt) are critical parameters for such devices. Pull-up transistors are P-type transistors, thus the threshold voltage of P-type GAA transistors used in SRAM devices is of particular importance. In at least some existing implementations, the threshold voltage of P-type GAA transistors used in SRAM devices, and the associated read margin, are not optimized and Vccmin is degraded. Additionally, with the continued scaling of device geometries, the metal gap-fill issue is limiting and continues to be a challenge.

Embodiments of the present disclosure offer advantages over the existing art, though it is understood that other embodiments may offer different advantages, not all advantages are necessarily discussed herein, and no particular advantage is required for all embodiments. For example, embodiments discussed herein include methods and structures for modulating the threshold voltage of P-type transistors (e.g., such as GAA transistors), including those used in SRAM devices, thereby providing SRAM read margin and Vccmin improvement. Stated another way, embodiments of the present disclosure provide a tunable threshold voltage for P-type transistors (e.g., such as GAA transistors). By way of example, the disclosed methods and structures for Vt tuning go beyond various conventional tuning approaches which primarily rely on modification of layer thicknesses. For instance, in some embodiments, modulation of the threshold voltage may be achieved by using a work function (WF) metal gate cap, such as a P-type work function (PWF) metal gate cap, that is formed over a gate dielectric layer. A “WF metal” or “WF metal gate cap”, in general and as used herein, may be used to describe one or more layers which are used to set a work function value for a gate electrode of a device (e.g., such as the PWF metal gate cap). In at least some existing implementations, a PWF metal gate cap includes a bi-layer stack having a layer of TaN disposed on top of a layer of TiN (TaN/TiN). In some cases, each of the TaN layer and the TiN layer may have a thickness of about 0.6 nm, for a total thickness of about 1.2 nm. By way of example, the PWF metal gate cap may be formed over a high-K (HK) dielectric/interfacial layer (IL) stack, and one or more of a glue layer, a fluorine-free W (FFW) layer, and a W layer may be formed over the PWF metal gate cap.

In accordance with embodiments of the present disclosure, threshold voltage modulation of P-type transistors may be achieved using a PWF metal gate cap that includes a tri-layer stack having a first layer of TiN, a second layer of TiN disposed over the first layer of TiN, and a third layer of TiN disposed over the second layer of TiN (Ti/Ti/Ti). Stated another way, various embodiments provide a PWF metal gate cap including a tri-layer stack, where each layer of the tri-layer stack is a nitrogen-containing layer. In some embodiments, each of the first nitrogen-containing layer (first TiN layer), the second nitrogen-containing layer (second TiN layer), and the third nitrogen-containing layer (third TiN layer) may have a substantially equal thickness of about 0.4 nm, for a total thickness of about 1.2 nm. Thus, while the total thickness of the PWF metal gate cap tri-layer stack may be substantially the same as that of at least some PWF metal gate cap bi-layer stacks, the composition of the material layers used to form the PWF metal gate cap has changed. More generally, and in various embodiments, each of the first nitrogen-containing layer (first TiN layer), the second nitrogen-containing layer (second TiN layer), and the third nitrogen-containing layer (third TiN layer) may have a substantially equal thickness in a range of about 0.4-1.6 nm, for a total thickness in a range of about 1.2-4.8 nm, depending on a P-type transistor type, as discussed below. To be sure, in some embodiments, the thickness of two or more of the first nitrogen-containing layer, the second nitrogen-containing layer, and the third nitrogen-containing layer may be different from each other, while the total thickness remains in a range of about 1.2-4.8 nm. In some embodiments, each of the first nitrogen-containing layer (first TiN layer), the second nitrogen-containing layer (second TiN layer), and the third nitrogen-containing layer (third TiN layer) may be deposited sequentially using separate deposition processes. It is noted that while various embodiments are discussed with reference to a PWF metal gate cap that includes three nitrogen-containing layers (e.g., TiN layers), some embodiments may include a PWF metal gate cap having more than or less than three nitrogen-containing layers. For instance, in at least some cases, the PWF metal gate cap includes a single nitrogen-containing layer deposited using a single deposition process.

In various embodiments, the additional layer surfaces/interfaces provided by the tri-layer stack of nitrogen-containing layers of the PWF metal gate cap may help to facilitate an increase in the concentration of oxygen within the PWF metal gate cap. In some embodiments, for example when the PWF metal gate cap includes more than three nitrogen-containing layers, the increase in the concentration of oxygen within the PWF metal gate cap may be larger (e.g., as compared to the tri-layer stack of nitrogen containing layers) due to the additional number of layer surfaces/interfaces. Likewise, when the PWF metal gate cap includes less than three nitrogen-containing layers, the increase in the concentration of oxygen within the PWF metal gate cap may be smaller (e.g., as compared to the tri-layer stack of nitrogen containing layers) due to the reduced number of layer surfaces/interfaces. In some cases, the concentration of oxygen may also increase within at least part of the HK dielectric/IL stack over which the PWF metal gate cap is formed. In some examples, the increased oxygen concentration modulates the flatband voltage (Vfb) of the device, which in turn modulates the threshold voltage (Vt), which is a function of Vfb. In some cases, prior to deposition of the PWF metal gate cap tri-layer stack, a plasma treatment process may be performed (e.g., such as an N₂ plasma treatment process or an NH₃ plasma treatment process), for example, to an exposed high-K dielectric layer. In some examples, the plasma treatment process may be performed after deposition of one or more of the first nitrogen-containing layer (first TiN layer), the second nitrogen-containing layer (second TiN layer), and the third nitrogen-containing layer (third TiN layer). In some cases, the combination of the PWF metal gate cap tri-layer stack and plasma treatment may provide a larger (e.g., around 2×, in some cases) flatband voltage shift (and thus a larger threshold voltage shift) than that provided by the PWF metal gate cap tri-layer stack without plasma treatment. As noted above, the disclosed PWF metal gate cap may be formed over a HK dielectric/IL stack, and one or more of a glue layer, a FFW layer, and a W layer may be formed over the PWF metal gate cap. In accordance with embodiments of the present disclosure, the PWF metal gate cap tri-layer stack (and optional plasma treatment process) provides for a tunable PU PFET Vt, as well as for improved SRAM read margin and Vccmin. It is also noted that while embodiments of the present disclosure may be primarily discussed with reference to P-type transistors, it will be understood that the embodiments disclosed herein may in some cases be applied to N-type transistors, where such implementations can be readily deduced by one skilled in the art, for example by symmetry to the P-type device implementations discussed herein. In addition, while some examples of work function metals have been given, it will be understood that in various embodiments work function metals may generally include TiN, TaN, TiAlC, TiAl, TiSiN, TaSi, TiAlN, a combination thereof, or other appropriate metal.

As noted above, embodiments of the present disclosure may be implemented within P-type PU transistors of SRAM devices. Generally, SRAM PU transistors operate at a standard Vt (SVT), for example, having a Vt in a range of between about 0.28V to 0.30V. In at least some examples, however, embodiments of the present disclosure may be implemented within other types of P-type transistors such as P-type logic transistors having a variety of different threshold voltages. For instance, some embodiments may be implemented within P-type logic transistors operating at SVT with Vt in a range of between about 0.28V to 0.30V, at low Vt (LVT) with Vt in a range of between about 0.26V to 0.28V, at ultra-low VT (uLVT) with Vt in a range of between about 0.24V to 0.26V, or at extremely-low VT (eLVT) with Vt in a range of between about 0.22V to 0.24V. To achieve the desired Vt for these different types of P-type logic transistors, the thickness of the PWF metal gate cap (e.g., the total thickness and/or the thickness of individual layers of the PWF metal gate cap) may be appropriately tuned based on the distance between adjacent GAA semiconductor channel layers and based on the desired Vt, as discussed in more detail below.

Embodiments of the present disclosure may also be simultaneously used to ameliorate the metal gap-fill issue (e.g., by use of ALD processing). As used herein, the term “gap fill issue” may be used to describe the challenge of gate metal fill (e.g., in a replacement metal gate process). In some existing processes, poor metal gate deposition may cause gaps or voids in the metal gate, detrimentally impacting device performance. Embodiments of the present disclosure, which may advantageously use ALD processing for metal gate layer deposition, provide high-quality, conformal metal gate layers that are substantially void-free and thereby effectively mitigate potential problems associated with the metal gap-fill issue. Other embodiments and advantages will be evident to those skilled in the art upon reading the present disclosure.

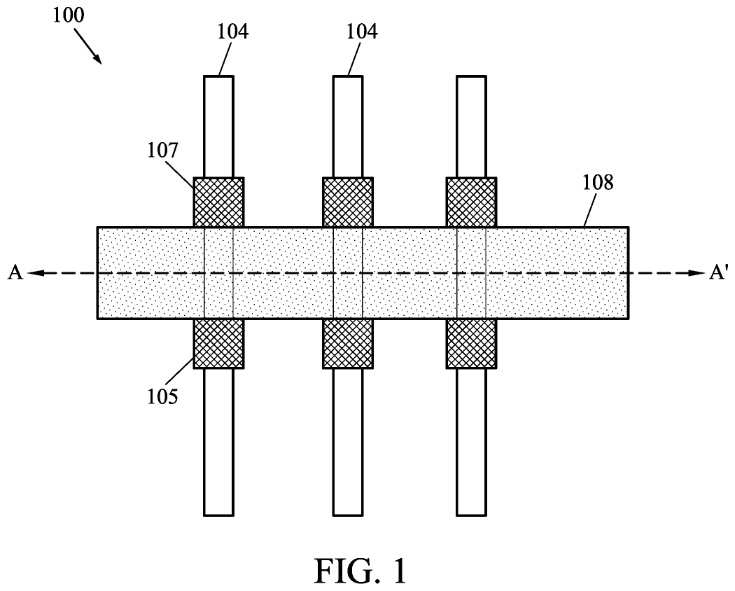

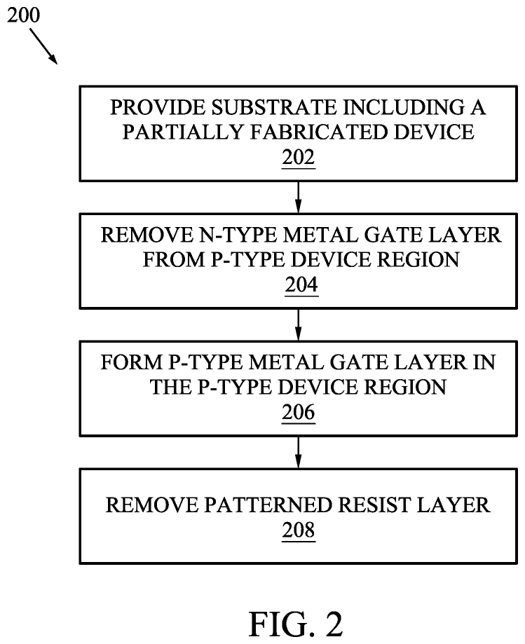

For purposes of the discussion that follows, FIG. 1 provides a simplified top-down layout view of a multi-gate device 100. In various embodiments, the multi-gate device 100 may include a FinFET device, a GAA transistor, or other type of multi-gate device. The multi-gate device 100 may include a plurality of fin elements 104 extending from a substrate, a gate structure 108 disposed over and around the fin elements 104, and source/drain features 105, 107 formed in source/drain regions adjacent to and on either side of the gate structure 108, where the source/drain features 105, 107 are formed in, on, and/or surrounding the fins 104. A channel region of the multi-gate device 100, which may include a plurality of semiconductor channel layers (e.g., when the multi-gate device 100 includes a GAA transistor), is disposed within the fins 104, underlying the gate structure 108, along a plane substantially parallel to a plane defined by section AA′ of FIG. 1. In some embodiments, sidewall spacers may also be formed on sidewalls of the gate structure 108. Various other features of the multi-gate device 100 are discussed in more detail below with reference to the method of FIG. 2.

Referring to FIG. 2, illustrated therein is a method 200 of semiconductor fabrication including fabrication of a semiconductor device 300 (e.g., which includes a multi-gate device), in accordance with various embodiments. The method 200 is discussed below with reference to fabrication of GAA transistors. However, it will be understood that aspects of the method 200 may be equally applied to other types of multi-gate devices, or to other types of devices implemented by the multi-gate devices, without departing from the scope of the present disclosure. In some embodiments, the method 200 may be used to fabricate the multi-gate device 100, described above with reference to FIG. 1. Thus, one or more aspects discussed above with reference to the multi-gate device 100 may also apply to the method 200. It is understood that the method 200 includes steps having features of a complementary metal-oxide-semiconductor (CMOS) technology process flow and thus, are only described briefly herein. Also, additional steps may be performed before, after, and/or during the method 200.

It is further noted that, in some embodiments, the semiconductor device 300 may include various other devices and features, such as other types of devices such as additional transistors, bipolar junction transistors, resistors, capacitors, inductors, diodes, fuses and/or other logic circuits, etc., but is simplified for a better understanding of the inventive concepts of the present disclosure. In some embodiments, the semiconductor device 300 include a plurality of semiconductor devices (e.g., transistors) which may be interconnected. Moreover, it is noted that the process steps of method 200, including any descriptions given with reference to the figures are merely exemplary and are not intended to be limiting beyond what is specifically recited in the claims that follow.

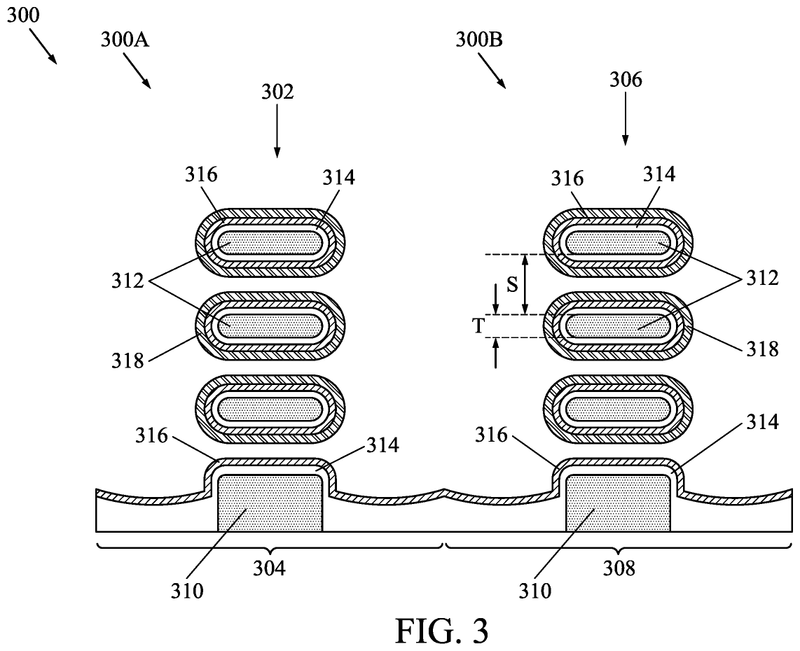

The method 200 begins at block 202 where a substrate including a partially fabricated device is provided. Referring to the example of FIG. 3, in an embodiment of block 202, a partially fabricated device 300 is provided. FIGS. 3, 4, 5, and 6 provide cross-sectional views of an embodiment of the semiconductor device 300 along a plane substantially parallel to a plane defined by section AA′ of FIG. 1 (e.g., along the direction of the gate structure 108).

The device 300 is formed on a substrate. In some embodiments, the substrate may be a semiconductor substrate such as a silicon substrate. The substrate may include various layers, including conductive or insulating layers formed on a semiconductor substrate. The substrate may include various doping configurations depending on design requirements as is known in the art. The substrate may also include other semiconductors such as germanium, silicon carbide (SiC), silicon germanium (SiGe), or diamond. Alternatively, the substrate may include a compound semiconductor and/or an alloy semiconductor. Further, the substrate may optionally include an epitaxial layer (epi-layer), may be strained for performance enhancement, may include a silicon-on-insulator (SOI) structure, and/or have other suitable enhancement features.

As shown in FIG. 3, the device 300 includes an N-type device 300A formed in an N-type device region 304 and a P-type device 300B formed in a P-type device region 308. In the present example, the N-type device region 304 and the P-type device region 308 are illustrated as being adjacent to each other. However, it will be understood that each of the N-type device region 304 and the P-type device region 308 may be formed in different areas of the substrate, without necessarily being directly adjacent to each other. In various embodiments, each of the N-type device 300A and the P-type device 300B include a partially-fabricated GAA transistor having a plurality of channels disposed in semiconductor channel layers. Specifically, in some examples, the N-type device 300A includes a fin 302 extending from the substrate and the P-type device 300B includes a fin 306 extending from the substrate. In some cases, shallow trench isolation (STI) features may be formed to isolate the fin 302 from the fin 306 or from other neighboring fins. In some embodiments, each of the fins 302, 306 may include a substrate portion 310 (formed from the substrate) and a plurality of epitaxial layers 312, where the epitaxial layers 312 include semiconductor channel layers. In an embodiment, the epitaxial layers 312 include silicon (Si).

In various embodiments, the epitaxial layers 312 may form a channel region of a GAA transistor, the channel region disposed between respective source/drain regions, for each of the N-type device 300A and the P-type device 300B. For example, as noted above, the epitaxial layers 312 may be referred to as semiconductor channel layers that are used to form a channel region of a GAA transistor. In various embodiments, the semiconductor channel layers (e.g., the layers 312 or portions thereof) may include nanosheet channel(s), nanowire channel(s), bar-shaped channel(s), and/or other suitable channel configurations. The semiconductor channel layers may also be used to form portions of the source/drain features of the GAA transistor, in some embodiments.

It is noted that while the fins 302, 306 are illustrated as including three (3) layers of the epitaxial layer 312, this is for illustrative purposes only and not intended to be limiting beyond what is specifically recited in the claims. It can be appreciated that any number of epitaxial layers can be formed, where for example, the number of epitaxial layers depends on the desired number of semiconductor channel layers for the GAA transistor. In some embodiments, the number of epitaxial layers 312, and thus the number of semiconductor channel layers, is between 3 and 10. In some embodiments, the epitaxial layers 312 (the semiconductor channel layers) each have a thickness ‘T’ in a range of about 5-15 nm and a spacing ‘S’ between adjacent epitaxial layers 312 (semiconductor channel layers) is in a range of about 5-8 nm. As noted above, the epitaxial layers 312 may serve as channel region(s) for a subsequently-formed multi-gate device (e.g., a GAA transistor) and its thickness, and spacing between adjacent epitaxial layers 312, may be chosen based at least in part on device performance considerations.

For example, in embodiments including P-type SRAM PU transistors (which may operate at SVT), the spacing ‘S’ between adjacent epitaxial layers 312 may be about 5 nm. For P-type logic transistors operating at SVT the spacing ‘S’ between adjacent epitaxial layers 312 may also be about 5 nm. For P-type logic transistors operating at LVT the spacing ‘S’ between adjacent epitaxial layers 312 may be about 6 nm. For P-type logic transistors operating at uLVT the spacing ‘S’ between adjacent epitaxial layers 312 may be about 7 nm. For P-type logic transistors operating at eLVT the spacing ‘S’ between adjacent epitaxial layers 312 may be about 8 nm. In various embodiments, and because of the differences in the spacing ‘S’ for the various types of P-type transistors, there will be more space or less space between adjacent epitaxial layers 312 within which to form the PWF metal gate cap. As a result, the thickness of the PWF metal gate cap may be appropriately tuned to be thicker or thinner, as discussed below, based on the spacing ‘S’ in order to achieve the desired Vt for the various types of P-type transistors.

In various embodiments, the fins 302, 306 and their respective semiconductor channel layers (the epitaxial layer 312) may be formed by growing an epitaxial layer stack of layers of a first composition interposed by layers of a second composition. The layers of the first composition may include the semiconductor channel layers (the epitaxial layer 312, which may include Si), and the layers of the second composition may include dummy layers (e.g., such as SiGe dummy layers). In some embodiments, epitaxial growth of the epitaxial layers stack is achieved by a molecular beam epitaxy (MBE) process, a chemical vapor deposition (CVD) process, a metalorganic chemical vapor deposition (MOCVD) process, other suitable epitaxial growth process, or combinations thereof.

Thereafter, a channel layer release process may be performed, where the dummy layers (e.g., SiGe dummy layers) in the channel regions of the device 300 may be selectively removed (e.g., using a selective etching process), while the semiconductor channel layers (the epitaxial layers 312) remain unetched. In some examples, selective removal of the dummy layers (e.g., the SiGe dummy layers) may be referred to as a channel layer release process (e.g., as the semiconductor channel layers are released from the dummy layers). In some embodiments, the selective etching process may include a selective wet etching process. In some cases, the selective wet etching includes ammonia and/or ozone. As merely one example, the selective wet etching process includes tetra-methyl ammonium hydroxide (TMAH). In some embodiments, the selective etching process may include a dry, plasma-free etching process performed using a CERTAS® Gas Chemical Etch System, available from Tokyo Electron Limited, Tokyo, Japan.

It is noted that as a result of the selective removal of the dummy layers (the SiGe dummy layers), gaps are formed between the adjacent semiconductor channel layers (the epitaxial layers 312) in the channel region of the device 300. By way of example, the gaps may serve to expose surfaces of the epitaxial layers 310, upon which one or more layers of a gate structure will be formed. For instance, as described in more detail below, portions of gate structures (e.g., including a metal gate stack having an interfacial layer, a high-K dielectric layer, and one or more metal electrode layers) will be formed within the gaps between adjacent semiconductor channel layers (the epitaxial layers 312). In some embodiments, after removing the dummy layers (the SiGe dummy layers), and prior to forming the portions of the gate structures, a sheet trim process (e.g., an etching process) may be performed to modify a profile of the semiconductor channel layers (e.g., the epitaxial layers 312) to achieve desired dimensions and/or desired shapes (e.g., cylindrical-shaped (e.g., nanowire), rectangular-shaped (e.g., nanobar), sheet-shaped (e.g., nanosheet), etc.) of the semiconductor channel layers.

Still referring to the example of FIG. 3, and in a further embodiment of block 202, an interfacial layer (IL) 314 is formed on exposed surfaces of the epitaxial layers 312 (semiconductor channel layers) and the substrate portion 310, including wrapping around (surrounding) the epitaxial layers 312 within the channel region of each of the N-type device 300A and the P-type device 300B. In some embodiments, a high-K dielectric layer 316 is then formed over the IL 314, including wrapping around (surrounding) the IL 314 formed on surfaces of the epitaxial layers 312. In various embodiments, the IL 314 and the high-K dielectric layer 316 may collectively define a gate dielectric of the gate structure for each of the N-type device 300A and the P-type device 300B. In some embodiments, the IL 314 has a thickness of about 0.5-1.5 nm, the high-K dielectric layer 316 has a thickness of about 1.5-2.5 nm, and the gate dielectric has a total thickness of about 2-4 nm. In at least one example, a ratio of the thickness of the high-K dielectric layer 316 to the thickness of the IL 314 may be about 2. Generally, and in various embodiments, the thicknesses of the IL 314 and the high-K dielectric layer 316 may be tuned for various types of transistors. High-K gate dielectrics, as used and described herein, include dielectric materials having a high dielectric constant, for example, greater than that of thermal silicon oxide (˜3.9).

In some embodiments, the IL 314 may include a dielectric material such as silicon oxide (SiO₂), HfSiO, or silicon oxynitride (SiON). In some examples, the high-K dielectric layer 316 may include hafnium oxide (HfO₂). Alternatively, the high-K dielectric layer 316 may include other high-K dielectrics, such as TiO₂, HfZrO, Ta₂O₃, HfSiO₄, ZrO₂, ZrSiO₂, LaO, AlO, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba,Sr)TiO₃ (BST), Al₂O₃, La₂O₃, Si₃N₄, oxynitrides (SiON), combinations thereof, or other suitable material. In various embodiments, the gate dielectric may be formed by thermal oxidation, ALD, physical vapor deposition (PVD), pulsed laser deposition (PLD), CVD, and/or other suitable methods.

After formation of the high-K dielectric layer 316, an N-type metal gate layer 318 may be deposited over the high-K dielectric layer 316, including wrapping around (surrounding) the high-K dielectric 316 within the channel region of each of the N-type device 300A and the P-type device 300B. While not explicitly shown, in some cases the N-type metal gate layer 318 may also be formed over the high-K dielectric layer 316 disposed over the substrate portion 310. In some embodiments, the N-type metal gate layer 318 may be deposited without merging between adjacent epitaxial layers 312 (semiconductor channel layers) or between the substrate portion 310 of fin 306 and a bottom epitaxial layer 312. In some embodiments, the N-type metal gate layer 318 includes TiAl, or other appropriate materials. In various examples, the N-type metal gate layer 318 may be equivalently referred to as an N-type work function (NWF) metal layer and may form part of a metal gate electrode (e.g., at least for the N-type device 300A). In some embodiments, the NWF metal layer may be used to set a value of a work function for a gate electrode for the N-type device 300A. In some embodiments, the N-type metal gate layer 318 may include a plurality of layers. In various examples, the N-type metal gate layer 318 may be formed using ALD. In some cases, the N-type metal gate layer 318 may alternately be formed using PVD, CVD, electron beam (e-beam) evaporation, and/or other suitable process.

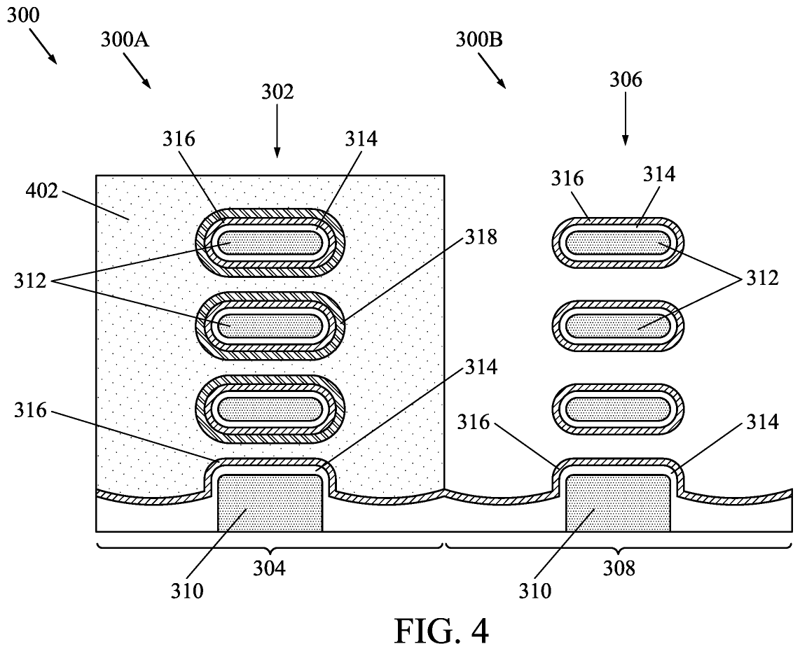

The method 200 proceeds to block 204 where an N-type metal gate layer is removed from a P-type device region. Referring to the example of FIGS. 3 and 4, in an embodiment of block 204, a photolithography and etching process may be performed to remove the N-type metal gate layer 318 from the P-type device region 308. For example, a photoresist (resist) layer may be deposited and patterned (e.g., by exposure and development of the resist) to form a patterned resist layer 402 which exposes the P-type device region 308 while the N-type device region 304 remains protected by the patterned resist layer 402. In some cases, a hard mask layer may be used in conjunction with the photoresist layer. For example, in some embodiments, a pattern formed in the resist layer may be transferred to an underlying hard mask layer (e.g., by etching), and the patterned hard mask layer may then be used to protect the N-type device region 304 when the P-type device region 308 is exposed. Whether or not a hard mask layer is used, and after exposure of the P-type device region 308, an etching process (e.g., wet etch, dry etch, or combination thereof) may be performed to remove the N-type metal gate layer 318 from the P-type device region 308.

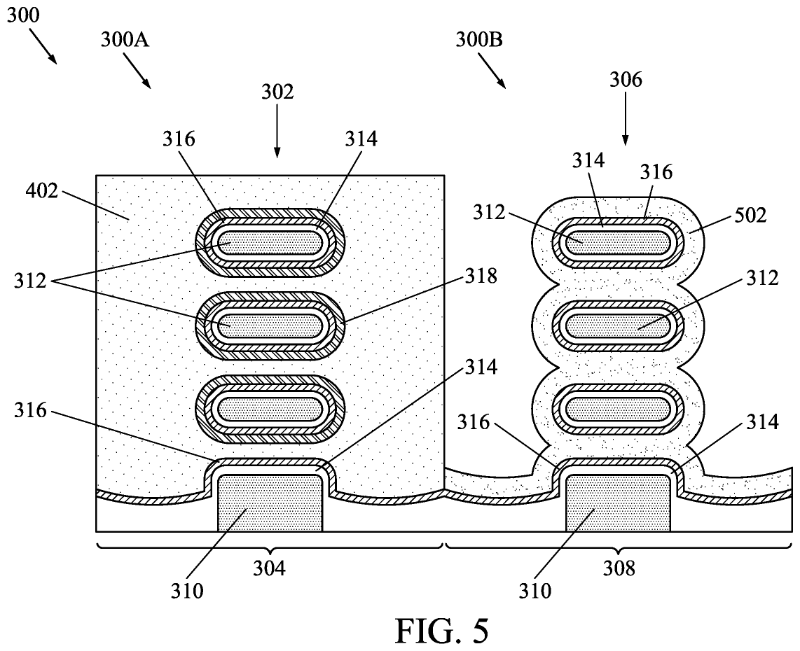

The method 200 proceeds to block 206 where a P-type metal gate layer is formed in a P-type device region. The P-type metal gate layer may include the PWF metal gate cap, described above. Referring to the example of FIGS. 4 and 5, in an embodiment of block 206, after removal of the N-type metal gate layer from the P-type device region (block 204), and while the N-type device region 304 remains protected by the patterned resist layer 402 (and/or a patterned hard mask layer), a PWF metal gate cap 502 may be formed over the high-K dielectric layer 316, including wrapping around (surrounding) the high-K dielectric layer 316 within the channel region of the exposed P-type device region 308. In some embodiments, the PWF metal gate cap 502 may merge between adjacent epitaxial layers 312 (semiconductor channel layers) and between the substrate portion 310 of fin 306 and a bottom epitaxial layer 312. By way of example, the PWF metal gate cap 502 may be equivalently referred to as a P-type work function (PWF) metal layer and may form part of a metal gate electrode for the P-type device 300B. Thus, in some embodiments, the PWF metal gate cap 502 may be used to set a value of a work function for a gate electrode for the P-type device 300B.

In various embodiments, the PWF metal gate cap 502 includes a tri-layer stack having a first layer of TiN, a second layer of TiN disposed over the first layer of TiN, and a third layer of TiN disposed over the second layer of TiN (Ti/Ti/Ti). Thus, each layer of the tri-layer stack of the PWF metal gate cap 502 is a nitrogen-containing layer. As noted above, and in various embodiments, each of the first nitrogen-containing layer (first TiN layer), the second nitrogen-containing layer (second TiN layer), and the third nitrogen-containing layer (third TiN layer) may have a thickness in a range of about 0.4-1.6 nm, for a total thickness in a range of about 1.2-4.8 nm, depending on a P-type transistor type. For instance, in embodiments implemented within P-type PU transistors of SRAM devices (e.g., operating at SVT) or within P-type logic transistors (e.g., operating at SVT), each of the first nitrogen-containing layer (first TiN layer), the second nitrogen-containing layer (second TiN layer), and the third nitrogen-containing layer (third TiN layer) may have a substantially equal thickness of about 0.4 nm, for a total thickness of about 1.2 nm. However, in some cases, the thickness of two or more of the first nitrogen-containing layer, the second nitrogen-containing layer, and the third nitrogen-containing layer may be different from each other, while the total thickness remains about 1.2 nm. Also, as noted above, the spacing ‘S’ between adjacent epitaxial layers 312 for P-type SRAM PU transistors (e.g., operating at SVT) and P-type logic transistors (e.g., operating at SVT) may be about 5 nm. Given that the IL 314 has a thickness of about 0.5-1.5 nm and the high-K dielectric layer 316 has a thickness of about 1.5-2.5 nm, setting the total thickness of the PWF metal gate cap 502 to be about 1.2 nm (e.g., for P-type PU transistors of SRAM devices and P-type logic transistors operating at SVT) ensures that a total thickness of the IL 314, the high-K dielectric layer 316, and the PWF metal gate cap 502 is less than or equal to the 5 nm spacing ‘S’ between adjacent epitaxial layers 312.

In embodiments implemented within P-type logic transistors (e.g., operating at LVT), each of the first nitrogen-containing layer (first TiN layer), the second nitrogen-containing layer (second TiN layer), and the third nitrogen-containing layer (third TiN layer) may have a substantially equal thickness of about 0.8 nm, for a total thickness of about 2.4 nm. However, in some cases, the thickness of two or more of the first nitrogen-containing layer, the second nitrogen-containing layer, and the third nitrogen-containing layer may be different from each other, while the total thickness remains about 2.4 nm. Also, as noted above, the spacing ‘S’ between adjacent epitaxial layers 312 for P-type logic transistors (e.g., operating at LVT) may be about 6 nm. Given that the IL 314 has a thickness of about 0.5-1.5 nm and the high-K dielectric layer 316 has a thickness of about 1.5-2.5 nm, setting the total thickness of the PWF metal gate cap 502 to be about 2.4 nm (e.g., for P-type logic transistors operating at LVT) ensures that a total thickness of the IL 314, the high-K dielectric layer 316, and the PWF metal gate cap 502 is less than or equal to the 6 nm spacing ‘S’ between adjacent epitaxial layers 312.

In embodiments implemented within P-type logic transistors (e.g., operating at uLVT), each of the first nitrogen-containing layer (first TiN layer), the second nitrogen-containing layer (second TiN layer), and the third nitrogen-containing layer (third TiN layer) may have a substantially equal thickness of about 1.2 nm, for a total thickness of about 3.6 nm. However, in some cases, the thickness of two or more of the first nitrogen-containing layer, the second nitrogen-containing layer, and the third nitrogen-containing layer may be different from each other, while the total thickness remains about 3.6 nm. Also, as noted above, the spacing ‘S’ between adjacent epitaxial layers 312 for P-type logic transistors (e.g., operating at uLVT) may be about 7 nm. Given that the IL 314 has a thickness of about 0.5-1.5 nm and the high-K dielectric layer 316 has a thickness of about 1.5-2.5 nm, setting the total thickness of the PWF metal gate cap 502 to be about 3.6 nm (e.g., for P-type logic transistors operating at uLVT) ensures that a total thickness of the IL 314, the high-K dielectric layer 316, and the PWF metal gate cap 502 is less than or equal to the 7 nm spacing ‘S’ between adjacent epitaxial layers 312.

In embodiments implemented within P-type logic transistors (e.g., operating at eLVT), each of the first nitrogen-containing layer (first TiN layer), the second nitrogen-containing layer (second TiN layer), and the third nitrogen-containing layer (third TiN layer) may have a substantially equal thickness of about 1.6 nm, for a total thickness of about 4.8 nm. However, in some cases, the thickness of two or more of the first nitrogen-containing layer, the second nitrogen-containing layer, and the third nitrogen-containing layer may be different from each other, while the total thickness remains about 4.8 nm. Also, as noted above, the spacing ‘S’ between adjacent epitaxial layers 312 for P-type logic transistors (e.g., operating at eLVT) may be about 8 nm. Given that the IL 314 has a thickness of about 0.5-1.5 nm and the high-K dielectric layer 316 has a thickness of about 1.5-2.5 nm, setting the total thickness of the PWF metal gate cap 502 to be about 4.8 nm (e.g., for P-type logic transistors operating at eLVT) ensures that a total thickness of the IL 314, the high-K dielectric layer 316, and the PWF metal gate cap 502 is less than or equal to the 8 nm spacing ‘S’ between adjacent epitaxial layers 312.

In some embodiments, each of the first nitrogen-containing layer (first TiN layer), the second nitrogen-containing layer (second TiN layer), and the third nitrogen-containing layer (third TiN layer) may be deposited sequentially using separate deposition processes. For example, in some cases, each of the first nitrogen-containing layer (first TiN layer), the second nitrogen-containing layer (second TiN layer), and the third nitrogen-containing layer (third TiN layer) may be deposited by separate, sequential ALD processes. In various embodiments, the ALD processes used to deposit each of the first, second, and third TiN layers may employ TiCl₄ and NH₃ as precursors. For instance, ALD TiN deposition may proceed by sequentially: (i) supplying a pulse of TiCl₄, (ii) performing a first purge using an inert gas (e.g., such as Ar gas), (iii) supplying a pulse of NH₃, and (iv) performing a second purge using an inert gas (e.g., such as Ar gas). Alternatively, in some cases, each of the first nitrogen-containing layer (first TiN layer), the second nitrogen-containing layer (second TiN layer), and the third nitrogen-containing layer (third TiN layer) may be deposited by separate, sequential PVD processes, CVD processes, e-beam evaporation processes, other suitable process, or a combination thereof.

In various embodiments, immediately prior to formation of the PWF metal gate cap 502, a plasma treatment process may be performed (e.g., to the exposed high-K dielectric layer 316). By way of example, the plasma treatment process may include an N₂ plasma treatment process or an NH₃ plasma treatment process. Additionally, in some cases, the plasma treatment process may be performed after deposition of each of the first nitrogen-containing layer (first TiN layer), the second nitrogen-containing layer (second TiN layer), and the third nitrogen-containing layer (third TiN layer). Alternatively, in some embodiments, the plasma treatment process may be performed after deposition of one or two of the first nitrogen-containing layer (first TiN layer), the second nitrogen-containing layer (second TiN layer), and the third nitrogen-containing layer (third TiN layer). Thus, the plasma treatment process may be performed in any combination including before the formation of the PWF metal gate cap 502 and/or after deposition of one or more of the first nitrogen-containing layer (first TiN layer), the second nitrogen-containing layer (second TiN layer), and the third nitrogen-containing layer (third TiN layer).

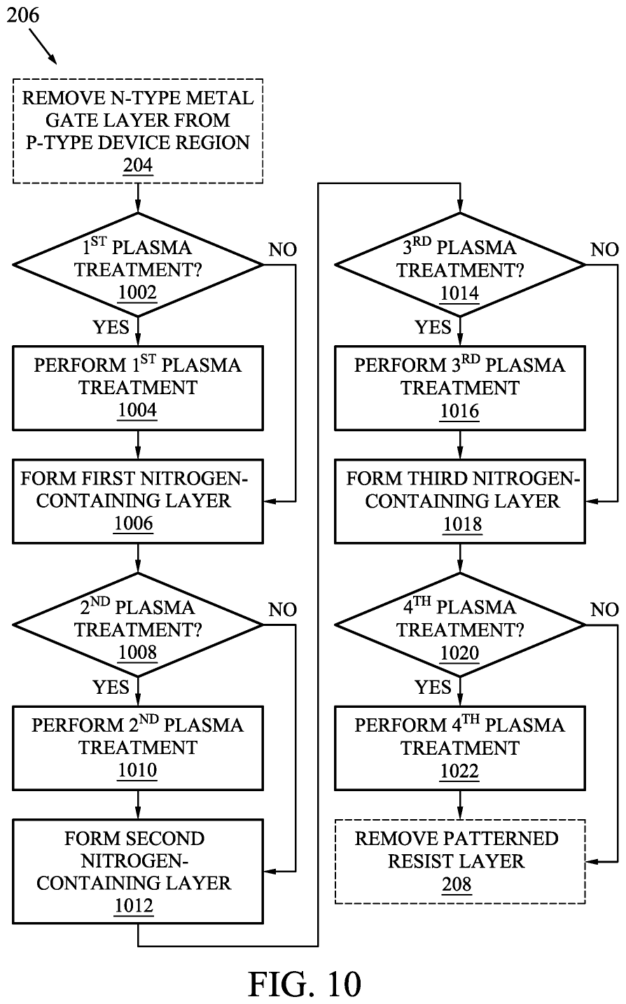

To further illustrate when the plasma treatment process may be performed, reference is made to FIG. 10, which illustrates a more detailed flow chart of a portion (block 206) of the method 200, in accordance with various embodiments. In some embodiments and after block 204 of the method 200, it is determined whether a first plasma treatment process will be performed (block 1002). If it is determined that the first plasma treatment process will be performed (block 1002), then the method proceeds to block 1004 where the first plasma treatment process (an N₂ plasma treatment process or an NH₃ plasma treatment process) is performed to the high-K dielectric layer 316. After performing the first plasma treatment process (block 1004), the method proceeds to block 1006 where the first nitrogen-containing layer (first TiN layer) is formed over the high-K dielectric layer 316, including wrapping around (surrounding) the high-K dielectric layer 316 within the channel region of the exposed P-type device region 308. However, if it is determined that the first plasma treatment process will not be performed (block 1002), then the method proceeds directly to block 1006 where the first nitrogen-containing layer (first TiN layer) is formed.

In some embodiments and after block 1006, it is determined whether a second plasma treatment process will be performed (block 1008). If it is determined that the second plasma treatment process will be performed (block 1008), then the method proceeds to block 1010 where the second plasma treatment process (an N₂ plasma treatment process or an NH₃ plasma treatment process) is performed to the first nitrogen-containing layer (first TiN layer). After performing the second plasma treatment process (block 1010), the method proceeds to block 1012 where the second nitrogen-containing layer (second TiN layer) is formed over the first nitrogen-containing layer. However, if it is determined that the second plasma treatment process will not be performed (block 1008), then the method proceeds directly to block 1012 where the second nitrogen-containing layer (second TiN layer) is formed.

In some embodiments and after block 1012, it is determined whether a third plasma treatment process will be performed (block 1014). If it is determined that the third plasma treatment process will be performed (block 1014), then the method proceeds to block 1016 where the third plasma treatment process (an N₂ plasma treatment process or an NH₃ plasma treatment process) is performed to the second nitrogen-containing layer (second TiN layer). After performing the third plasma treatment process (block 1016), the method proceeds to block 1018 where the third nitrogen-containing layer (third TiN layer) is formed over the second nitrogen-containing layer. However, if it is determined that the third plasma treatment process will not be performed (block 1014), then the method proceeds directly to block 1018 where the third nitrogen-containing layer (third TiN layer) is formed.

In some embodiments and after block 1018, it is determined whether a fourth plasma treatment process will be performed (block 1020). If it is determined that the fourth plasma treatment process will be performed (block 1020), then the method proceeds to block 1022 where the fourth plasma treatment process (an N₂ plasma treatment process or an NH₃ plasma treatment process) is performed to the third nitrogen-containing layer (third TiN layer). After performing the fourth plasma treatment process (block 1022), the method proceeds to block 208 of the method 200. However, if it is determined that the fourth plasma treatment process will not be performed (block 1020), then the method proceeds directly to block 208 of the method 200.

It is also noted that, in various embodiments, the plasma treatment process may be performed at a temperature between about 300-500° C., at a pressure of between about 0.5-1.5 Torr, and at a power of between about 10-50 W. In some cases, the parameters for the plasma treatment process may be selected based in part on the type of transistor being fabricated. For instance, in embodiments implemented within P-type PU transistors of SRAM devices (e.g., operating at SVT) or within P-type logic transistors (e.g., operating at SVT), the plasma treatment process may be performed at a temperature of about 400° C., at a pressure of about 1 Torr, and at a power of about 30 W. For devices operating at threshold voltages higher than SVT, the plasma treatment process may be performed at a temperature of less than about 400° C., at a pressure of less than about 1 Torr, and at a power of less than about 30 W. Alternatively, for devices operating at threshold voltages lower than SVT, the plasma treatment process may be performed at a temperature of greater than about 400° C., at a pressure of greater than about 1 Torr, and at a power of greater than about 30 W. In various embodiments, the parameters for the plasma treatment process may also be selected to avoid any nitrogen (N₂) contamination or implantation into the device (e.g., within the layer receiving the plasma treatment process).

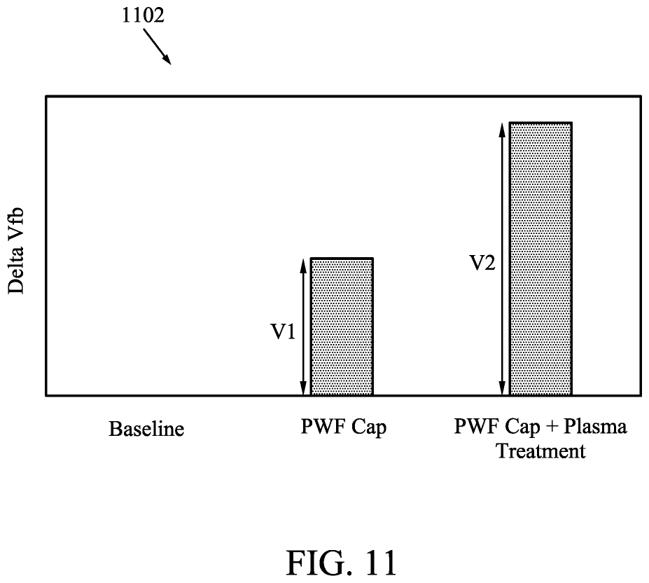

As previously noted, the tri-layer stack of the PWF metal gate cap 502 provides additional layer surfaces/interfaces which may help to facilitate an increase in the concentration of oxygen within the PWF metal gate cap 502 and/or within at least part of the high-K dielectric layer 316/IL 314 stack over which the PWF metal gate cap 502 is formed. In various embodiments, the increased oxygen concentration will modulate the flatband voltage (Vfb) of the P-type device 300B, which in turn modulates the threshold voltage (Vt), as described in more detail below. In some embodiments, the plasma treatment process (N₂ plasma treatment or NH₃ plasma treatment) may be used to further increase the oxygen concentration and to remove any interfacial layer (e.g., an interfacial layer formed on a TiN surface, such as an oxide layer) prior to formation of a subsequent layer, thereby improving device performance. For purposes of illustration, reference is made to graph 1102 of FIG. 11, which compares the flatband voltage shift (delta Vfb) ‘V1’ of a device with the PWF metal gate cap 502, but without plasma treatment, and the flatband voltage shift (delta Vfb) ‘V2’ of a device with the PWF metal gate cap 502 and plasma treatment, to a baseline device (e.g., fabricated according to at least some existing implementations). As an example, the delta Vfb ‘V1’ of the device with the PWF metal gate cap 502 (but no plasma treatment) may be equal to between about 40-50 mV, and the delta Vfb ‘V2’ of the device with the PWF metal gate cap 502 and plasma treatment may be equal to between about 80-100 mV. Thus, in various embodiments, the combination of the PWF metal gate cap 502 and plasma treatment may provide a larger (e.g., around 2×) flatband voltage shift (and thus a larger threshold voltage shift) than that provided by the PWF metal gate cap 502 without the plasma treatment. As such, embodiments of the present disclosure provide for a tunable Vt for the P-type device 300B, which when used to implement an SRAM device, provides for improved SRAM read margin and Vccmin.

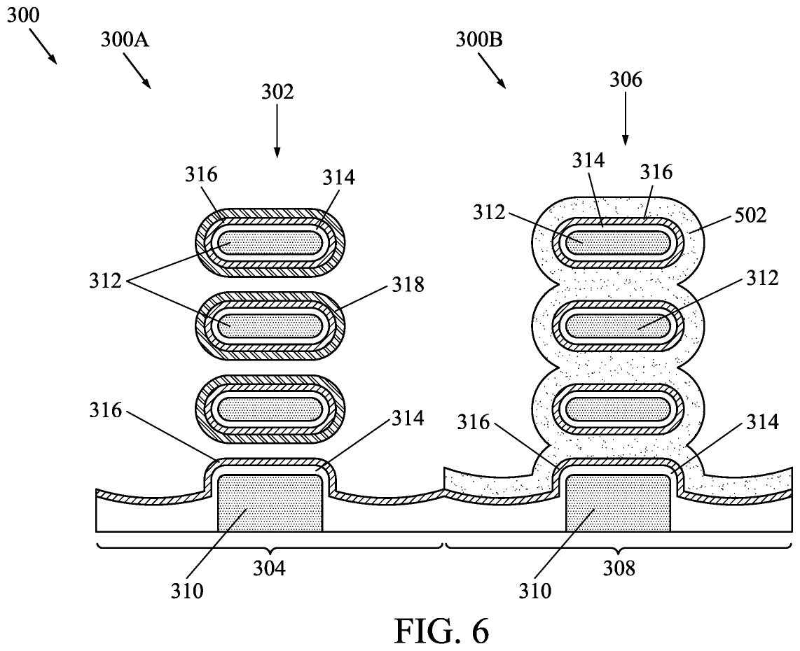

The method 200 proceeds to block 208 where a patterned resist layer is removed. Referring to the example of FIGS. 5 and 6, in an embodiment of block 208, after formation of the PWF metal gate cap 502 (block 206), the patterned resist layer 402 (and/or the patterned hard mask layer) is removed from the N-type device region 304 to expose the N-type metal gate layer 318. In some embodiments, the patterned resist layer 402 may be removed using a wet etch, a dry etch, or a combination thereof. After removal of the patterned resist layer 402, and in some embodiments, one or more subsequent layers may be deposited over the PWF metal gate cap 502 (in the P-type device region 308) and over the N-type metal gate layer 318 (in the N-type device region 304). In some embodiments, the one or more subsequently deposited layers may also be part of the gate electrode for each of the N-type device 300A (in the N-type device region 304) and the P-type device 300B (in the P-type device region 308). In some examples, the one or more subsequently deposited layers may include a glue layer, a fluorine-free tungsten (FFW) layer formed over the glue layer, and a tungsten (W) fill layer formed over the FFW layer. In various examples, the glue layer, the FFW layer, and W fill layer may also be part of the gate electrode for each of the N-type device 300A (in the N-type device region 304) and the P-type device 300B (in the P-type device region 308). In addition, and in some embodiments, ALD processing may be used for deposition of the various gate electrode layers, discussed above, thereby providing high-quality, conformal metal gate layers that are substantially void-free. As a result, embodiments of the present disclosure effectively mitigate potential problems associated with the gap fill issue.

The device 300 fabricated according to the method 200 may undergo further processing to form various features and regions known in the art. For example, subsequent processing may form various contacts/vias/lines and multilayers interconnect features (e.g., metal layers and interlayer dielectrics) on the substrate including the device 300, configured to connect the various features to form a functional circuit that may include one or more devices (e.g., one or more of the N-type device 300A and the P-type device 300B). In furtherance of the example, a multilayer interconnection may include vertical interconnects, such as vias or contacts, and horizontal interconnects, such as metal lines. The various interconnection features may employ various conductive materials including copper, tungsten, and/or silicide. In one example, a damascene and/or dual damascene process is used to form a copper related multilayer interconnection structure. Moreover, additional process steps may be implemented before, during, and after the method 200, and some process steps described above may be replaced or eliminated in accordance with various embodiments of the method 200.

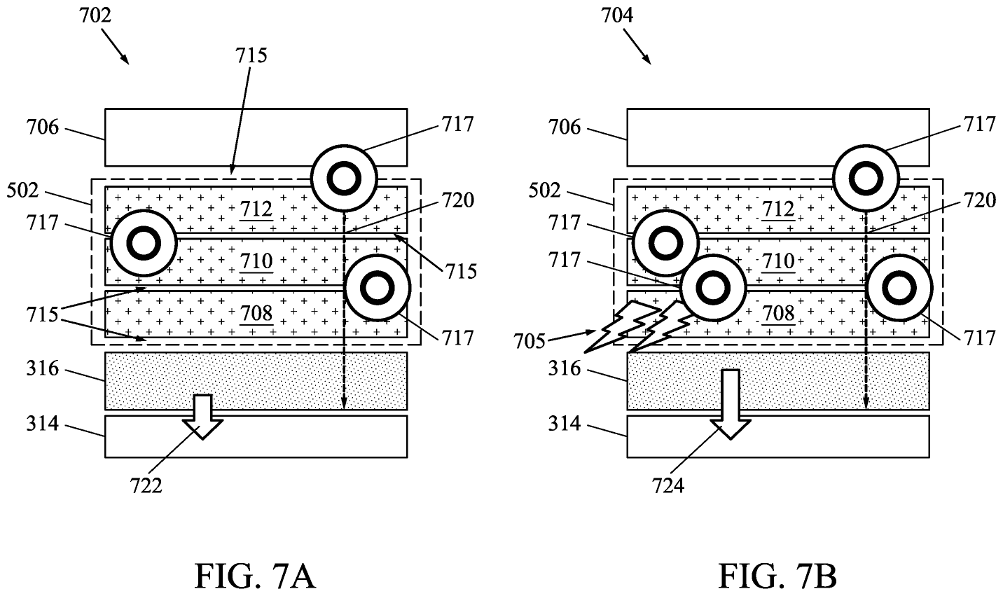

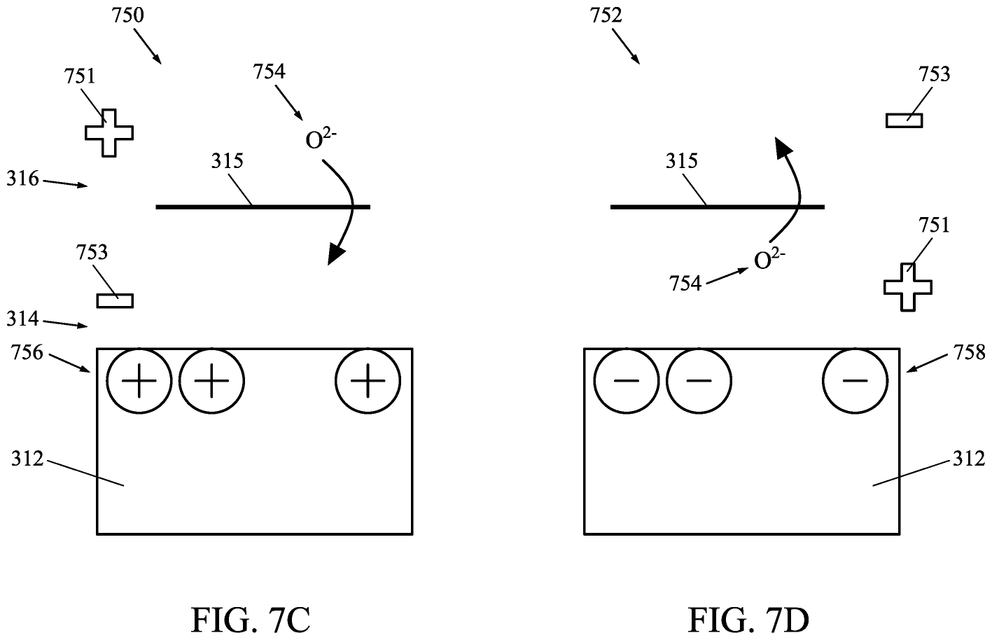

Elaborating on the physical mechanism by which the tunable Vt is provided, reference is made to FIGS. 7A and 7B, which illustrate enlarged views of a gate stack for P-type devices 702, 704, which may be substantially the same as the P-type device 300B, discussed above. By way of example, the device 702 of FIG. 7A has been fabricated to include the PWF metal gate cap 502, but the plasma treatment process has not been performed. Therefore, in some cases, the device 702 may include an interfacial layer (e.g., oxide layer) between adjacent nitrogen-containing layers of the PWF metal gate cap 502. In contrast, the device 704 of FIG. 7B has been fabricated using a combination of both the PWF metal gate cap 502 and a plasma treatment process 705. Thus, the device 704 will have a larger flatband voltage shift (and thus a larger threshold voltage shift) than the device 702 and will be substantially free of an interfacial layer (e.g., oxide layer) between adjacent nitrogen-containing layers of the PWF metal gate cap 502.

Each of the devices 702, 704 include the IL 314, the high-K dielectric layer 316 formed over the IL 314, the PWF metal gate cap 502 formed over the high-K dielectric layer 316, and subsequent layers 706 formed over the PWF metal gate cap 502, as previously discussed. By way of example, and in various embodiments, the PWF metal gate cap 502 includes a first nitrogen-containing layer 708 (first TiN layer), a second nitrogen-containing layer 710 (second TiN layer), and a third nitrogen-containing layer 712 (third TiN layer). Additionally, in some examples, the subsequent layers 706 may include a glue layer, a fluorine-free tungsten (FFW) layer formed over the glue layer, and a tungsten (W) fill layer formed over the FFW layer. It is noted in the example of FIGS. 7A/7B, adjacent layers (e.g., the IL 314, the high-K dielectric layer 316, the first nitrogen-containing layer 708, the second nitrogen-containing layer 710, the third nitrogen-containing layer 712, and the subsequent layers 706) are depicted as having spaces therebetween. This is merely for purposes of illustration, and it will be understood that adjacent layers will be in contact with each other in a final device configuration. In addition, as noted above, the device 702 may in some embodiments include an interfacial layer (e.g., oxide layer) between adjacent nitrogen-containing layers of the PWF metal gate cap 502.

In various cases, the tri-layer stack of the PWF metal gate cap 502 (e.g., the first nitrogen-containing layer 708, the second nitrogen-containing layer 710, the third nitrogen-containing layer 712) provides additional layer surfaces/interfaces 715 which may help to facilitate an increase in the concentration of oxygen atoms 717 within the PWF metal gate cap 502 and/or within at least part of the high-K dielectric layer 316/IL 314 stack. In some examples, the increase in the oxygen concentration resulting from the formation of the PWF metal gate cap 502 also provides for (or induces) the formation of a dipole 722, 724 (e.g., at an interface between the high-K dielectric layer 316 and the IL 314). In an example, oxygen atoms 717 within the PWF metal gate cap 502 may migrate towards the high-K dielectric layer 316/IL 314 stack, as indicated by arrows 720. The dipole 722, 724 may be formed based on a difference in the areal density of oxygen atoms (σ). It is noted that for purposes of this disclosure, oxygen concentration and areal density of oxygen atoms (σ) may at times be used interchangeably, as an increase/decrease in oxygen concentration may be expected to imply a corresponding increase/decrease in the areal density of oxygen atoms (σ). After the diffusion 720, and in some examples, the σ difference at the high-K dielectric layer 316/IL 314 interface should be compensated for by oxygen transfer from a higher-σ region (one of the high-K dielectric layer 316 or IL 314) to a lower-σ region (the other of the high-K dielectric layer 316 or IL 314). In addition, the oxygen may transfer in a form of O²⁻ which may create positively-charged vacancies (Vo²⁺) in the higher-σ region and a negative charged center in the lower-σ region. This may be the origin of the interface dipole 722, 724. It is noted that the dipole 724 of the device 704 may be larger than the dipole 722 of the device 702 since the device 704 was fabricated using a combination of both the PWF metal gate cap 502 and the plasma treatment process 705, which further increases the oxygen concentration, while the device 702 omitted the plasma treatment process 705. Thus, the device 704 will have a larger flatband voltage shift (and thus a larger threshold voltage shift) than the device 702. For instance, the modulation in the flatband voltage (Vfb) of the device 704 may be around 2× larger than the modulation of the flatband voltage of the device 702 (e.g., as compared to a baseline device fabricated according to at least some existing implementations). In addition, depending on the material used for the high-K dielectric layer 316, an orientation of the dipole 722, 724 (e.g., vector of the dipole moment) may be reversed as compared to the orientation shown in FIGS. 7A/7B. Thus, in various cases, a direction (positive/negative) of the flatband voltage shift (and the threshold voltage shift) may likewise be tuned (e.g., for application to either P-type or N-type transistors). Further, depending on the material used for the high-K dielectric layer 316, a magnitude of the dipole 722, 724 may be increased or decreased to provide transistors operating at a variety of threshold voltages (e.g., such as SVT, LVT, uLVT, eLVT, and HVT).

Referring to FIGS. 7C/7D, illustrated therein are some examples of controlling the dipole orientation and magnitude based on the material used for the high-K dielectric layer 316. Specifically, and in accordance with various embodiments, FIG. 7C illustrates a P-type device 750, and FIG. 7D illustrates an N-type device 752. Each of the devices 750, 752 include a semiconductor channel layer (e.g., such as the epitaxial layer 312), an IL 314 formed over the semiconductor channel layer, and a high-K dielectric layer 316 formed over the IL 314. In the present example, a horizontal line 315 is used to denote a physical boundary between the IL 314 and the high-K dielectric layer 316. For the present discussion, it is assumed that the IL 314 includes silicon oxide (SiO₂), the high-K dielectric layer 316 includes Al₂O₃ or HfO₂ for P-type devices such as the P-type device 750, and the high-K dielectric layer 316 includes Y₂O₃ or La₂O₃ for N-type devices such as the N-type device 752.

Generally, selection of the material for the high-K dielectric layer 316 may be largely based on the difference in the areal density of oxygen atoms (σ) between a given high-K material and SiO₂ (σ_{SiO2}). For instance, for P-type devices such as the P-type device 750, the areal density of oxygen atoms (σ) in Al₂O₃ and HfO₂ may both be larger than that of SiO₂, while the areal density of oxygen atoms (σ) in Al₂O₃ is larger than that of HfO₂. For N-type devices such as the N-type device 752, the areal density of oxygen atoms (σ) in Y₂O₃ and La₂O₃ may both be less than that of SiO₂, while the areal density of oxygen atoms (σ) in La₂O₃ is less than that of Y₂O₃. Due to the differences in areal densities of oxygen atoms (σ) as compared to SiO₂, a P-type device (such as the P-type device 750) employing Al₂O₃ will have a larger flatband voltage shift (and larger threshold voltage shift) than a P-type device employing HfO₂. Likewise, an N-type device (such as the N-type device 752) employing La₂O₃ will have a larger flatband voltage shift (and larger threshold voltage shift) than an N-type device employing Y₂O₃.

With reference to the P-type device 750 of FIG. 7C, where the areal density of oxygen atoms (σ) in the high-K dielectric layer 316 is larger than that of the IL 314, oxygen 754 is transferred across the boundary 315 (from the high-K dielectric layer 316 to the IL 314) in the form of O²⁻ to create a positive charge center (denoted by plus sign 751) in the high-K dielectric layer 316 and a corresponding negative charge center (denoted by negative sign 753) in the IL 314, thereby forming a P-dipole in the P-type device 750. The P-dipole, in turn, will attract holes 756 in the semiconductor channel layer (e.g., the epitaxial layer 312) to modulate the flatband voltage (and threshold voltage) of the P-type device 750. Referring to the N-type device 752 of FIG. 7D, where the areal density of oxygen atoms (σ) in the high-K dielectric layer 316 is less than that of the IL 314, oxygen 754 is transferred across the boundary 315 (from the IL 314 to the high-K dielectric layer 316) in the form of O²⁻ to create a positive charge center (denoted by plus sign 751) in the IL 314 and a corresponding negative charge center (denoted by negative sign 753) in the high-K dielectric layer 316, thereby forming an N-dipole in the N-type device 752. The N-dipole, in turn, will attract electrons 758 in the semiconductor channel layer (e.g., the epitaxial layer 312) to modulate the flatband voltage (and threshold voltage) of the N-type device 752. It is also noted that, in various embodiments, the flatband voltage shift (and corresponding threshold voltage shift) provided by the selection of a particular material for the high-K dielectric layer 316 may be enhanced by use of the PWF metal gate cap 502 and the optional plasma treatment process, as discussed above.

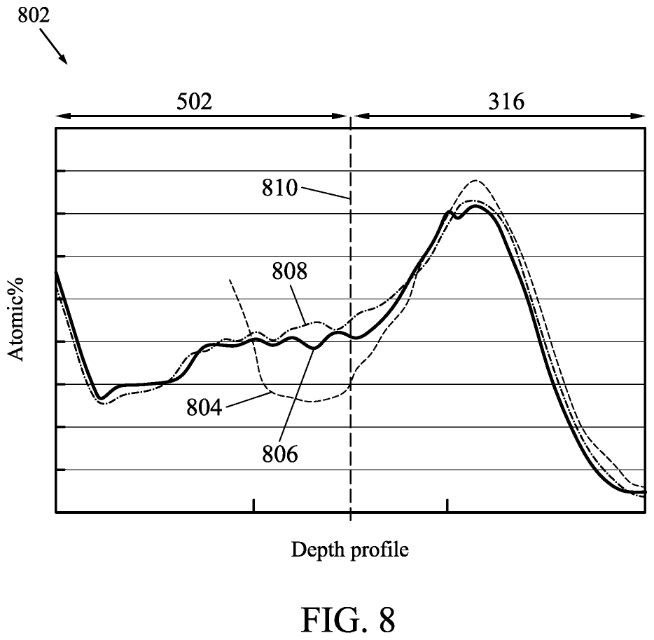

With reference to FIG. 8, illustrated therein is a plot 802 showing the relative atomic percent of oxygen (along the Y-axis) as a function of depth (along the X-axis) across the PWF metal gate cap 502 and the high-K dielectric layer 316 for a baseline device 804 (e.g., fabricated according to at least some existing implementations), a device 806 (e.g., fabricated to include the PWF metal gate cap 502, but without the plasma treatment process), and a device 808 (e.g., fabricated using a combination of both the PWF metal gate cap 502 and a plasma treatment process). As shown, the device 808 generally exhibits the largest atomic percent of oxygen, while both the device 806 and the device 808 exhibit a larger atomic percent of oxygen than the device 804, particularly in a region near an interface 810 between the PWF metal gate cap 502 and the high-K dielectric layer 316.

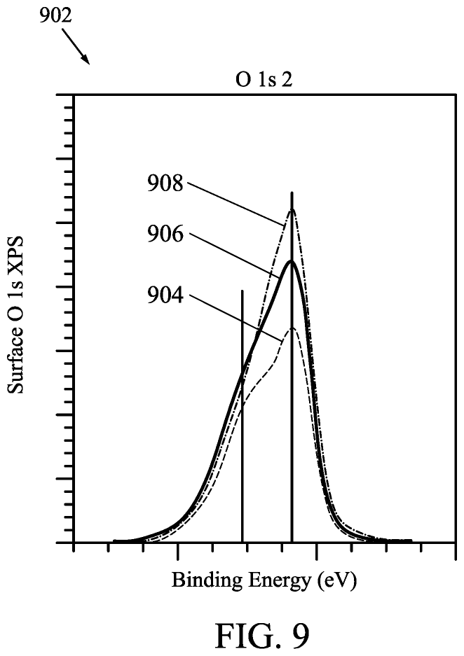

Referring to FIG. 9, illustrated therein is a plot 902 of X-ray photoelectron spectroscopy (XPS) data showing the relative intensity (counts per second) of the oxygen (is) signal (along the Y-axis) as a function of binding energy (eV) (along the X-axis), in a range of about 525-540 eV, for a baseline device 904 (e.g., fabricated according to at least some existing implementations), a device 906 (e.g., fabricated to include the PWF metal gate cap 502, but without the plasma treatment process), and a device 908 (e.g., fabricated using a combination of both the PWF metal gate cap 502 and a plasma treatment process). The plot 902 provides further confirmation of the previously discussed results, where the device 908 (PWF metal gate cap 502 and plasma treatment process) exhibits the largest amount of oxygen, followed by the device 906 (PWF metal gate cap 502 without plasma treatment process), and lastly the device 904 (baseline device with neither the PWF metal gate cap 502 nor the plasma treatment process).

The various embodiments described herein offer several advantages over the existing art. It will be understood that not all advantages have been necessarily discussed herein, no particular advantage is required for all embodiments, and other embodiments may offer different advantages. As one example, embodiments discussed herein include methods and structures for modulating the threshold voltage of P-type transistors (e.g., such as GAA transistors), including those used in SRAM devices, thereby providing SRAM read margin and Vccmin improvement. In some embodiments, modulation of the threshold voltage may be achieved by using a PWF metal gate cap that includes a tri-layer stack having a first nitrogen-containing layer (first TiN layer), a second nitrogen-containing layer (second TiN layer), and a third nitrogen-containing layer (third TiN layer). In various embodiments, the additional layer surfaces/interfaces provided by the tri-layer stack of nitrogen-containing layers of the PWF metal gate cap may help to facilitate an increase in the concentration of oxygen within the PWF metal gate cap. In some cases, the concentration of oxygen may also increase within at least part of the high-K dielectric/IL stack, and may form a dipole at the high-K dielectric/IL interface. In some examples, the increased oxygen concentration modulates the flatband voltage (Vfb) of the device, which in turn modulates the threshold voltage (Vt). In some cases, prior to deposition of the PWF metal gate cap tri-layer stack, a plasma treatment process may be performed (e.g., such as an N₂ plasma treatment process or an NH₃ plasma treatment process). In some examples, the plasma treatment process may be performed after deposition of one or more of the first nitrogen-containing layer (first TiN layer), the second nitrogen-containing layer (second TiN layer), and the third nitrogen-containing layer (third TiN layer). In addition, embodiments of the present disclosure may be simultaneously used to ameliorate the metal gap-fill issue (e.g., by use of ALD processing). Other embodiments and advantages will be evident to those skilled in the art upon reading the present disclosure.

Thus, one of the embodiments of the present disclosure described a method for fabricating a semiconductor device that includes providing a fin extending from a substrate. In some embodiments, the fin includes a plurality of semiconductor channel layers defining a channel region for a P-type transistor. In some examples, the method further includes forming a gate dielectric wrapping around each of the plurality of semiconductor channel layers of the P-type transistor. In some cases, the method further includes forming a PWF metal gate cap wrapping around the gate dielectric. In various embodiments, the PWF metal gate cap merges between adjacent semiconductor channel layers of the plurality of semiconductor channel layers. Additionally, in some examples, the PWF metal gate cap includes a plurality of nitrogen-containing layers.

In another of the embodiments, discussed is a method that includes providing a first fin in an N-type device region and a second fin in a P-type device region. In some embodiments, each of the first and second fins include a plurality of semiconductor channel layers. In various examples, the method further includes forming a gate dielectric surrounding each of the plurality of semiconductor channel layers within each of the N-type device region and the P-type device region. In some embodiments, the method further includes forming an N-type metal gate layer surrounding the gate dielectric within each of the N-type device region and the P-type device region. After forming the N-type metal gate layer, and in some embodiments, the method further includes removing the N-type metal gate layer from the P-type device region. After removing the N-type metal gate layer from the P-type device region, and in various examples, the method further includes forming a PWF metal gate cap over the gate dielectric within the P-type device region. In some embodiments, the PWF metal gate cap includes a plurality of nitrogen-containing layers.

In yet another of the embodiments, discussed is a semiconductor device including a first fin extending from a substrate within a P-type device region. In some embodiments, the first fin includes a first plurality of semiconductor channel layers. In various examples, the semiconductor device further includes a first gate dielectric wrapping around each of the first plurality of semiconductor channel layers. In various embodiments, the semiconductor device further includes a PWF metal gate cap wrapping around the first gate dielectric. In some embodiments, the PWF metal gate cap merges between adjacent semiconductor channel layers of the first plurality of semiconductor channel layers. Additionally, in some embodiments, the PWF metal gate cap includes a plurality of nitrogen-containing layers.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of fabricating a semiconductor device, comprising:
providing a fin extending from a substrate, wherein the fin includes a plurality of semiconductor channel layers defining a channel region for a P-type transistor;
forming a gate dielectric wrapping around each of the plurality of semiconductor channel layers of the P-type transistor;
forming a P-type work function (PWF) metal gate cap wrapping around the gate dielectric, wherein the PWF metal gate cap merges between adjacent semiconductor channel layers of the plurality of semiconductor channel layers, and wherein the PWF metal gate cap includes a plurality of nitrogen-containing layers.

2. The method of claim 1, wherein the plurality of nitrogen-containing layers includes a first layer of TiN, a second layer of TiN disposed over the first layer of TiN, and a third layer of TiN disposed over the second layer of TiN.

3. The method of claim 1, further comprising:
prior to forming the PWF metal gate cap, performing a plasma treatment process to the gate dielectric.

4. The method of claim 2, further comprising:
after forming at least one of the first layer of TiN, the second layer of TiN, and the third layer of TiN, performing a plasma treatment process to the respective one of the first layer of TiN, the second layer of TiN, and the third layer of TiN.

5. The method of claim 3, wherein the plasma treatment process includes an N₂ plasma treatment process or an NH₃ plasma treatment process.

6. The method of claim 1, wherein the gate dielectric includes an interfacial layer (IL) and a high-K dielectric layer disposed over the IL, and wherein a dipole is formed at an interface between the IL and the high-K dielectric layer.

7. The method of claim 1, further comprising:
prior to forming the PWF metal gate cap, removing an N-type metal gate layer wrapped around the gate dielectric to expose the gate dielectric; and
forming the PWF metal gate cap wrapping around the exposed gate dielectric.

8. The method of claim 2, wherein each of the first layer of TiN, the second layer of TiN, and the third layer of TiN are deposited sequentially using separate deposition processes.

9. The method of claim 1, wherein the P-type transistor includes a P-type gate-all-around (GAA) device, and wherein the P-type GAA device provides a pull-up transistor for a static random-access memory (SRAM) device.

10. The method of claim 1, further comprising:
after forming the PWF metal gate cap, depositing one or more subsequent layers over the PWF metal gate cap, wherein the one or more subsequent layers includes a glue layer, a fluorine-free tungsten (FFW) layer, and a tungsten (W) fill layer.

11. A method, comprising:
providing a first fin in an N-type device region and a second fin in a P-type device region, wherein each of the first and second fins include a plurality of semiconductor channel layers;
forming a gate dielectric surrounding each of the plurality of semiconductor channel layers within each of the N-type device region and the P-type device region;
forming an N-type metal gate layer surrounding the gate dielectric within each of the N-type device region and the P-type device region;
after forming the N-type metal gate layer, removing the N-type metal gate layer from the P-type device region; and
after removing the N-type metal gate layer from the P-type device region, forming a P-type work function (PWF) metal gate cap over the gate dielectric within the P-type device region, wherein the PWF metal gate cap includes a plurality of nitrogen-containing layers.

12. The method of claim 11, further comprising:
after forming the N-type metal gate layer and prior to removing the N-type metal gate layer from the P-type device region, depositing and patterning a photoresist layer so that the P-type device region is exposed while the N-type device region remains protected by the patterned photoresist layer; and
removing the N-type metal gate layer from the exposed P-type device region.

13. The method of claim 11, wherein the plurality of nitrogen-containing layers includes a first layer of TiN, a second layer of TiN disposed over the first layer of TiN, and a third layer of TiN disposed over the second layer of TiN.

14. The method of claim 11, wherein prior to forming the PWF metal gate cap, performing an N₂ plasma treatment process or an NH₃ plasma treatment process.

15. The method of claim 11, wherein forming the PWF metal gate cap modulates a flatband voltage (Vfb) of a P-type transistor formed in the P-type device region.

16. The method of claim 11, further comprising:
after forming the PWF metal gate cap, depositing one or more subsequent layers over the PWF metal gate cap, wherein the one or more subsequent layers includes a glue layer, a fluorine-free tungsten (FFW) layer, and a tungsten (W) fill layer.

17. A semiconductor device, comprising:
a first fin extending from a substrate within a P-type device region, wherein the first fin includes a first plurality of semiconductor channel layers;
a first gate dielectric wrapping around each of the first plurality of semiconductor channel layers; and
a P-type work function (PWF) metal gate cap wrapping around the first gate dielectric, wherein the PWF metal gate cap merges between adjacent semiconductor channel layers of the first plurality of semiconductor channel layers, and wherein the PWF metal gate cap includes a plurality of nitrogen-containing layers.

18. The semiconductor device of claim 17, wherein the plurality of nitrogen-containing layers includes a first layer of TiN, a second layer of TiN disposed over the first layer of TiN, and a third layer of TiN disposed over the second layer of TiN.

19. The semiconductor device of claim 18, wherein each of the first layer of TiN, the second layer of TiN, and the third layer of TiN have a substantially equal thickness.

20. The semiconductor device of claim 17, further comprising:
a second fin extending from the substrate within an N-type device region adjacent to the P-type device region, wherein the second fin includes a second plurality of semiconductor channel layers;
a second gate dielectric wrapping around each of the second plurality of semiconductor channel layers; and
an N-type metal gate layer wrapping around the second gate dielectric without merging between adjacent semiconductor channel layers of the second plurality of semiconductor channel layers.
